(19) United States
(12) Patent Application Publication
(10) Pub. No.: US 2013/0200378 A1
(43) Pub. Date: Aug. 8, 2013

(54) METHOD AND APPARATUS FOR FORMING ORGANIC MATERIAL PATTERN, ORGANIC LIGHT EMITTING DISPLAY APPARATUS, AND METHOD OF MANUFACTURING ORGANIC LIGHT EMITTING DISPLAY APPARATUS

(71) Applicants: Jung-Tae Park, Yongin-city (KR); Seog-Young Lee, Seoul (KR)

(72) Inventors: Jung-Tae Park, Yongin-city (KR); Seog-Young Lee, Seoul (KR)

(21) Appl. No.: 13/588,789

(22) Filed: Aug. 17, 2012

(30) Foreign Application Priority Data
Feb. 7, 2012 (KR) 10-2012-0012541

(51) Int. Cl. H01L 27/15; H05B 3/00; H01L 33/36; H05B 33/10

(52) U.S. Cl. 257/59; 427/66; 156/60; 219/200; 257/72; 438/34; 257/E27.121; 257/E33.062

(57) ABSTRACT

A method and an apparatus for forming an organic material pattern in a desired pattern on a substrate to improve device durability and image quality characteristics, an organic light emitting display apparatus, and a method of manufacturing an organic light emitting display apparatus, are provided. The apparatus includes a heater overlapping with a region of the substrate different from another region of the substrate in which the organic material pattern is to be formed, a power source for applying a voltage to the heater, and wiring for electrically connecting the power source with the heater.

### CROSS-REFERENCE TO RELATED PATENT APPLICATION

This application claims priority to and the benefit of Korean Patent Application No. 10-2012-0012541, filed on Feb. 7, 2012, in the Korean Intellectual Property Office, the disclosure of which is incorporated herein in its entirety by reference.

### BACKGROUND

1. Field

One or more aspects of the present invention relate to a method and apparatus for forming an organic material pattern, an organic light emitting display apparatus, and a method of manufacturing an organic light emitting display apparatus.

2. Description of the Related Art

An organic layer pattern containing an organic material may be used for various purposes. For example, the organic layer pattern may be used in a flat panel display apparatus.

From among flat panel display apparatuses, an organic light emitting display apparatus includes an organic layer pattern. The organic light emitting display apparatus is a self-emitting display apparatus that has a larger viewing angle, better contrast characteristics, and a faster response speed as compared to other commonly used displays in the related art. Thus, the organic light emitting display apparatus has drawn attention as a next-generation display apparatus.

However, an organic layer pattern is not easy to manufacture because an organic material is vulnerable to moisture.

Thus, it is not easy to exactly manufacture an organic light emitting display apparatus with an organic layer pattern according to a desired design. Accordingly, it is desirable to improve the durability and image quality characteristics of an organic light emitting display apparatus.

### SUMMARY

One or more embodiments of the present invention provide a method and an apparatus for forming an organic material pattern to improve device durability and image quality characteristics, an organic light emitting display apparatus, and a method of manufacturing an organic light emitting display apparatus.

According to an embodiment of the present invention, there is provided an apparatus for forming an organic material pattern in a desired shape on a substrate, the apparatus including a heater overlapping with a region of the substrate different from another region of the substrate in which the organic material pattern is to be formed; a power source for applying a voltage to the heater; and wiring for electrically connecting the power source and the heater.

The heater may include connection members and a body member. The connection members may respectively form both ends of the heater to be connected to the wiring, and the body member may be located between the connection members.

The heater may be formed on a surface of the substrate on which the organic material pattern is to be formed.

The heater may be formed on a surface of the substrate opposite to another surface of the substrate on which the organic material pattern is to be formed.

The apparatus may further include a base member facing a surface of the substrate opposite to another surface of the substrate on which the organic material pattern is to be formed. The heater may be formed on a surface of the base member facing the substrate.

The heater may be in contact with the substrate.

According to another embodiment of the present invention, there is provided a method of forming an organic material pattern in a desired shape on a substrate, the method including preparing a heater to overlap with a region of the substrate different from another region of the substrate in which the organic material pattern is to be formed, a power source to apply voltage to the heater, and wiring to electrically connect the power source with the heater; forming an organic material layer on the substrate, the organic material layer being a material for forming the organic material pattern; and applying a voltage to the heater from the power source to remove at least a region of the organic material layer corresponding in position to the heater by using joule heat generated by the heater.

The heater may include connection members and a body member. The connection members may respectively form both ends of the heater to be connected to the wiring. The body member may be located between the connection members.

The heater may be formed on a surface of the substrate, and the organic material layer may be formed on the surface of the substrate and cover the heater.

The heater may be formed on a surface of the substrate opposite to another surface of the substrate on which the organic material pattern is to be formed.

The method may further include preparing a base member to face a surface of the substrate opposite to another surface of the substrate on which the organic material pattern is to be formed on the substrate, wherein the heater is formed on a surface of the base member facing the surface of the substrate. The substrate may face the heating unit, and the organic material layer may be formed on the another surface of the substrate opposite to the surface of the substrate facing the heater.

The heater may be in contact with the substrate.

The organic material pattern may include an aperture corresponding in position to the heater.

According to another embodiment of the present invention, there is provided an organic light emitting display apparatus, the apparatus including a substrate; a display unit on the substrate and including an organic light emitting device, the organic light emitting device including a first electrode, a second electrode, and an intermediate layer, the intermediate layer being disposed between the first electrode and the second electrode and including an organic emission layer; a heater adjacent to the display unit; and an organic material pattern, the organic material pattern and the heater overlapping with different regions of the substrate, respectively.

The apparatus may further include a sealing substrate facing the substrate; and a sealing member between the substrate and the sealing substrate and adjacent to the display unit. A region of the heater may overlap with the sealing member.

A bottom surface of the sealing member may be spaced apart from at least the organic material pattern.

The sealing member may be spaced apart from the organic material pattern.

The apparatus may further include at least one insulating layer between the heater and the sealing member.

The apparatus may further include a thin film transistor (TFT) being electrically connected to the organic light emitting device, the TFT including an active layer, a gate electrode, a source electrode, and a drain electrode. The heater may include a material used to form at least one from among the gate electrode, the source electrode, and drain electrode.

The apparatus may further include an interlayer insulating layer between the gate electrode and the source electrode, and between the gate electrode and the drain electrode. The heater may include a material used to form the gate electrode, and the interlayer insulating layer may be formed on the heater.

The organic material pattern may include a material used to form the intermediate layer.

The organic material pattern may be connected to a region of the intermediate layer.

Ends of the heater may correspond to end portions of the substrate, respectively.

The heater may include connection members and a body member. The connection members may respectively form both ends of the heater. The body member may be located between the connection members. The connection members may be formed to respectively correspond to end portions of the substrate in such a manner that side surfaces of the connection members are exposed.

According to another embodiment of the present invention, there is provided a method of manufacturing an organic light emitting display apparatus, the method including forming a display unit on a substrate, the display unit including an organic light emitting device, the organic light emitting device including a first electrode, a second electrode, and an intermediate layer, the intermediate layer being between the first electrode and the second electrode and comprising an organic emission layer; forming a heater adjacent to the display unit; forming an organic material layer on the substrate; and applying a voltage to the heater from a power source to remove at least a region of the organic material layer corresponding in position to the heater by using joule heat generated by the heater.

If the voltage is applied to the heater from the power source to remove at least the region of the organic material layer corresponding in position to the heater by using the joule heat generated by the heater, then an organic material pattern having an aperture corresponding in position to the heater may be formed.

The power source and the heater may be electrically connected via wiring.

The organic material layer may increase a material used to form the intermediate layer during the formation of the intermediate layer.

The method may further include preparing a sealing substrate to face the substrate; and forming a sealing member between the substrate and the sealing substrate, and adjacent to the display unit. The sealing member may overlap with at least a region of the heater.

The forming of the sealing member may be performed after the heater is formed and the region of the organic material layer corresponding in position to the heater has been removed.

The sealing member may be formed to be disposed apart from the organic material layer.

The method may further include forming at least one insulating layer between the heater and the sealing member.

The method may further include forming a thin film transistor (TFT) to be electrically connected to the organic light emitting device, the TFT including an active layer, a gate electrode, a source electrode, and a drain electrode. The heater may include a material used to form at least one from among the gate electrode, the source electrode, and the drain electrode.

### BRIEF DESCRIPTION OF THE DRAWINGS

The above and other features and aspects of the present invention will become more apparent by describing in detail exemplary embodiments thereof with reference to the attached drawings in which:

FIG. 1 is a schematic plan view of an apparatus for forming an organic material pattern, according to an embodiment of the present invention;

FIG. 2 is a cross-sectional view taken along the line II-II of FIG. 1;

FIGS. 3A and 3B are cross-sectional views illustrating a method of forming an organic material pattern by using the apparatus illustrated in FIGS. 1 and 2, according to an embodiment of the present invention;

FIG. 4 is a schematic plan view of an apparatus for forming an organic material pattern, according to another embodiment of the present invention;

FIG. 5 is a cross-sectional view taken along the line V-V of FIG. 4;

FIGS. 6A and 6B are cross-sectional views illustrating a method of forming an organic material pattern by using the apparatus illustrated in FIGS. 4 and 5, according to another embodiment of the present invention;

FIG. 7 is a schematic plan view of an apparatus for forming an organic material pattern, according to another embodiment of the present invention;

FIG. 8 is a cross-sectional view taken along the line VIII-VIII of FIG. 7;

FIGS. 9A and 9B are cross-sectional views illustrating a method of forming an organic material pattern by using the apparatus illustrated in FIGS. 7 and 8, according to another embodiment of the present invention;

FIG. 10 is a schematic plan view of an organic light emitting display apparatus according to an embodiment of the present invention;

FIG. 11 is a cross-sectional view taken along the line XI-XI of FIG. 10; and

FIGS. 12A is a schematic plan view, and FIGS. 12B through 12E are cross-sectional views; FIGS. 12A through 12E sequentially illustrate a method of manufacturing the organic light emitting display apparatus illustrated in FIGS. 10 and 11, according to an embodiment of the present invention.

### DETAILED DESCRIPTION

Hereinafter, exemplary embodiments of the present invention will be described in greater detail with reference to the accompanying drawings. Expressions such as “at least one of,” when preceding a list of elements, modify the entire list of elements and do not modify the individual elements of the list.

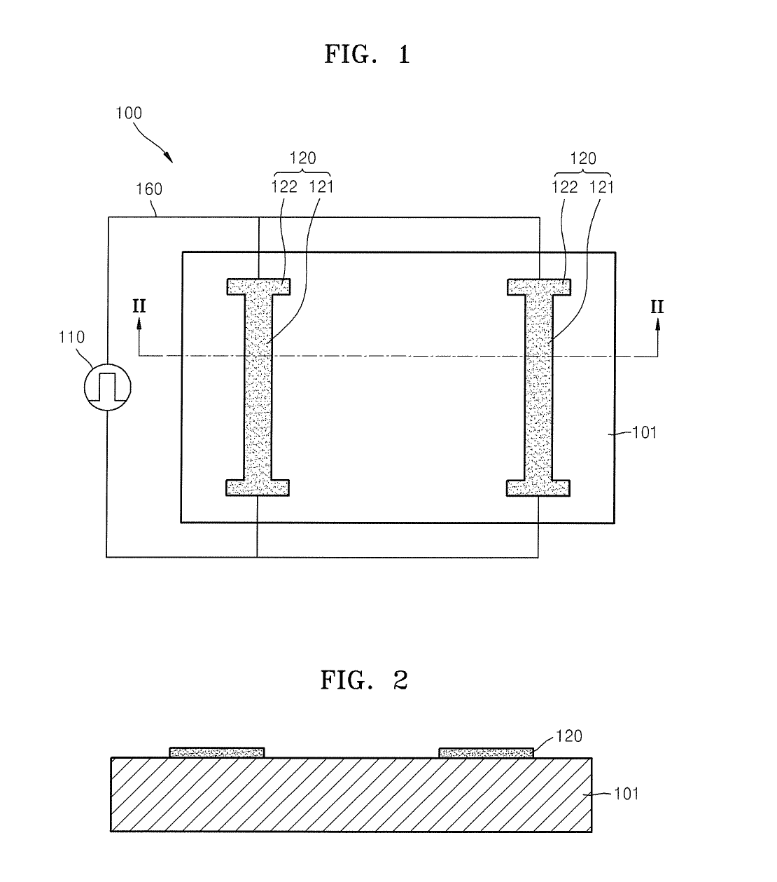

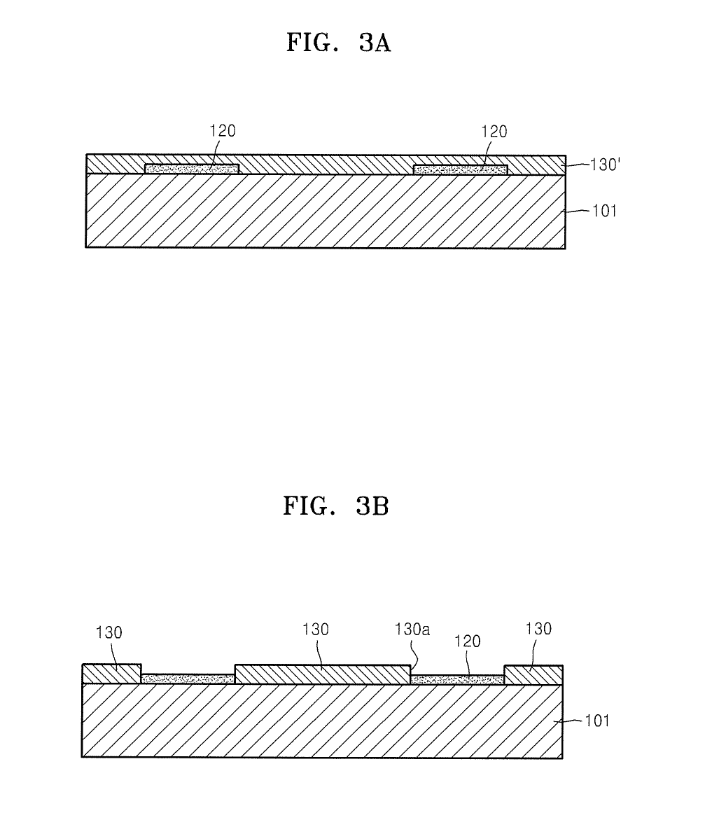

FIG. 1 is a schematic plan view of an apparatus 100 for forming an organic material pattern, according to an embodiment of the present invention. FIG. 2 is a cross-sectional view taken along the line II-II of FIG. 1.

Referring to FIGS. 1 and 2, the apparatus 100 is used to form a desired organic material pattern on a substrate 101.

To this end, heating units 120 (e.g., heaters) are disposed on the substrate 101. The heating units 120 are electrically connected to a power source 110 via a wiring unit 160 (e.g., wirings).

The substrate 101 may be formed of a SiO₂-based transparent glass material, but the present invention is not limited thereto and the substrate 101 may be formed of a suitable heat-resistant material.

The heating units 120 are formed in a set or predetermined pattern on the substrate 101. The heating units 120 may have any of various patterns. A pattern of the heating units 120 may be determined according to a shape of an organic material pattern to be formed on the substrate 101.

Each of the heating units 120 includes a body member 121 and connection members 122. The connection members 122 respectively form both ends of the heating unit 120. The body member 121 is located between the connection members 122. When a voltage is applied to the heating units 120 by the power source 110, the heating units 120 generate joule heat. To this end, the heating units 120 may be formed of metal having a preselected or predetermined resistance.

The wiring unit 160 is connected to the heating units 120. More specifically, the wiring unit 160 is connected to the connection members 122 of the heating units 120. The wiring unit 160 is formed of a conductive material (e.g., metal).

The power source 110 is electrically connected to the wiring unit 160. The type of the power source 110 is not limited. In other words, any of various types of devices capable of applying a suitable voltage to the heating units 120, and controlling a level of the voltage to be applied to the heating units 120 and a period of time for applying the voltage, may be employed as the power source 110.

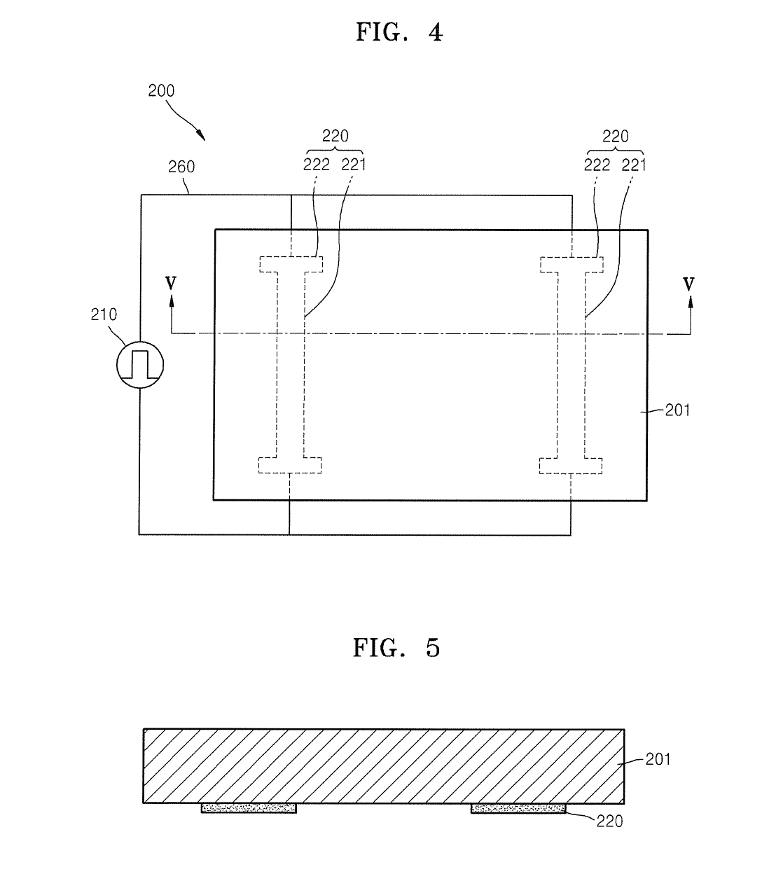

FIGS. 3A and 3B are cross-sectional views illustrating a method of forming an organic material pattern by using the apparatus 100 illustrated in FIGS. 1 and 2, according to an embodiment of the present invention.

First, referring to FIG. 3A, an organic material layer 130′ that is a material for forming an organic material pattern 130 is formed on a substrate 101. More specifically, the organic material layer 130′ is formed on a surface of the substrate 101 on which the heating units 120 are disposed. In this case, the organic material layer 130′ is formed on the entire surface of the substrate 101 on which the heating units 120 are disposed to cover the heating units 120.

Then, referring to FIG. 3B, a voltage is applied to the heating units 120 to form the organic material pattern 130, as will be described in detail below.

A suitable voltage is applied to the heating units 120 by using the power source 110 of FIG. 1. When the voltage is applied to the heating units 120, joule heat is generated by the heating unit 120 due to a preselected or predetermined resistance of the heating units 120. The generated joule heat is intensively delivered to regions of the organic material layer 130′ that overlap with the heating units 120. Thus, the overlapping regions of the organic material layer 130′ are melted and substantially removed by the joule heat.

Thus, the organic material pattern 130 is formed having apertures 130a corresponding to the heating units 120. That is, the heating units 120 do not overlap with the organic material pattern 130 formed from the organic material layer 130′. In other words, the organic material pattern 130 and the heating units overlap with different regions (e.g., mutually exclusive regions) of a substrate, respectively.

In the current embodiment, the organic material pattern 130 may be formed using joule heat generated by the heating units 120 without having to use a wet process, e.g., a photolithographic process, thereby protecting the organic material pattern 130 from moisture. Accordingly, it is possible to form the organic material pattern 130 having high durability in a precise pattern.

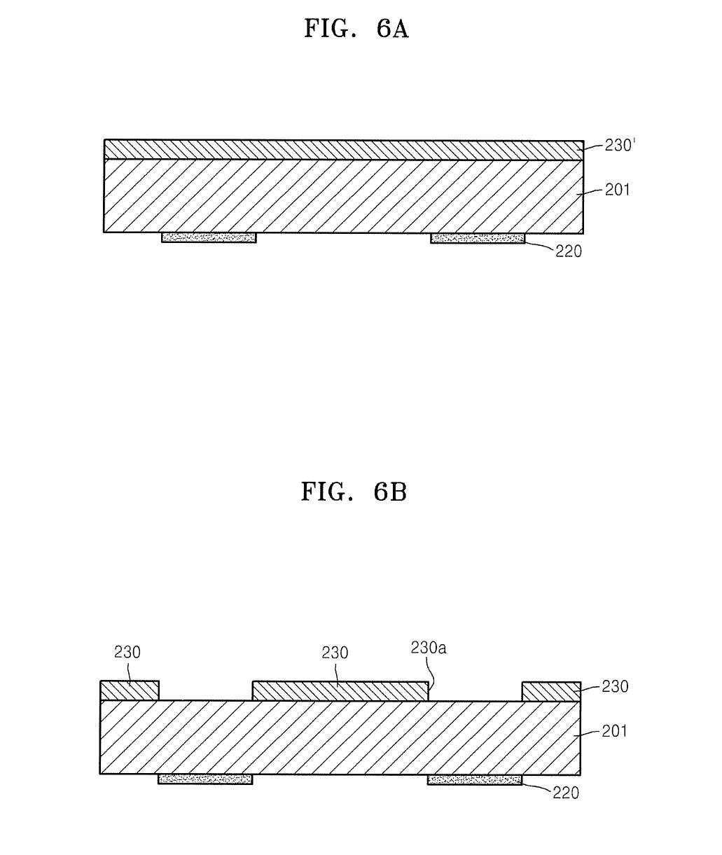

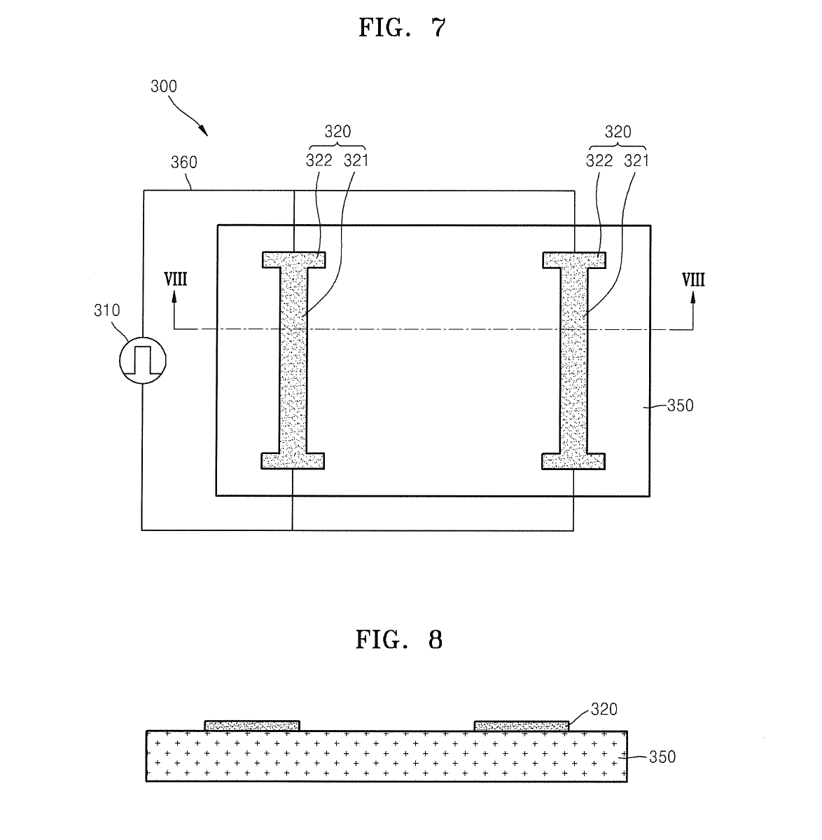

FIG. 4 is a schematic plan view of an apparatus 200 for forming an organic material pattern, according to another embodiment of the present invention. FIG. 5 is a cross-sectional view taken along the line V-V of FIG. 4.

Referring to FIGS. 4 and 5, the apparatus 200 is used to form a desired organic material pattern on a substrate 201.

To this end, heating units 220 are disposed on the substrate 201. The heating units 220 are electrically connected to a power source 210 via a wiring unit 260.

The substrate 201 may be formed of a SiO₂-based transparent glass material, but the present invention is not limited thereto and the substrate 201 may be formed of a material having high heat resistance and conductivity.

The heating units 220 are formed in a preselected or predetermined pattern on a bottom surface of the substrate 201. The heating units 220 may have any of various patterns. A pattern of the heating units 220 may be determined according to a desired shape of an organic material pattern to be formed on the substrate 201.

Each of the heating units 220 includes a body member 221 and connection members 222. The connection members 222 respectively form both ends of the heating unit 220. The body member 221 is located between the connection members 222. When a voltage is applied to the heating units 220 by the power source 210, the heating units 220 generate joule heat. To this end, the heating units 220 may be formed of metal having a preselected or predetermined resistance.

The wiring unit 260 is connected to the heating units 220. More specifically, the wiring unit 260 is connected to the connection members 222 of the heating units 220. The wiring unit 260 is formed of a conductive material (e.g., metal).

The power source 210 is electrically connected to the wiring unit 260. The type of the power source 210 is not limited. In other words, any of various types of devices capable of applying a suitable voltage to the heating units 220, and controlling a level of the voltage to be applied to the heating units 220 and a period of time for applying the voltage, may be employed as the power source 210.

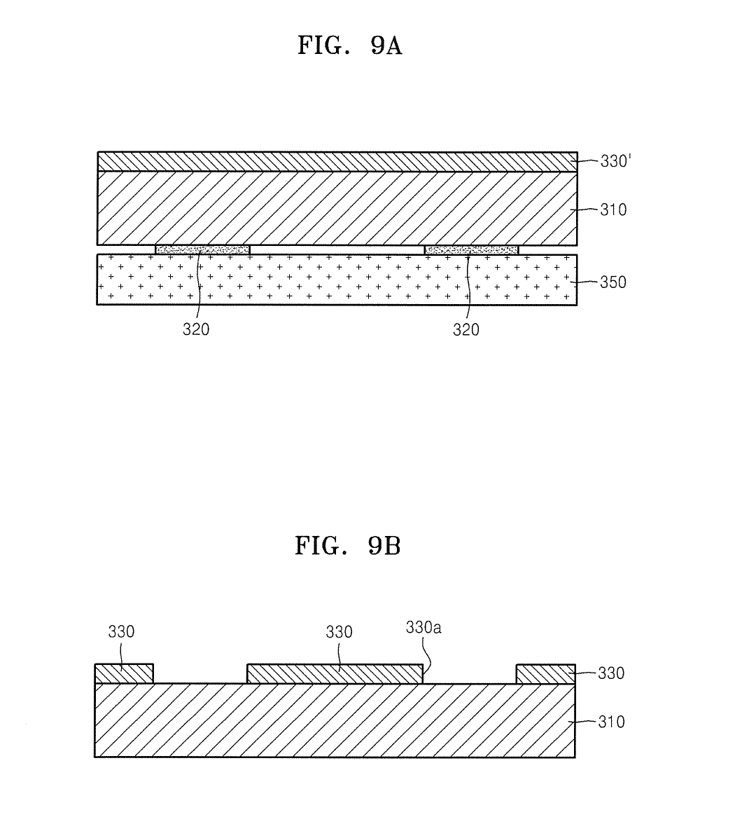

FIGS. 6A and 6B are cross-sectional views illustrating a method of forming an organic material pattern by using the apparatus 200 illustrated in FIGS. 4 and 5, according to another embodiment of the present invention.

First, referring to FIG. 6A, an organic material layer 230′ that is a material for forming an organic material pattern 230 is formed on a substrate 201. More specifically, the organic material layer 230′ is formed on a surface of the substrate 201 opposite to another surface of the substrate 201 on which the heating units 220 are disposed. That is, the heating units 220 are formed on the bottom surface of the substrate 201, and the organic material layer 230′ is formed on a top surface of the substrate 201.

In this case, the organic material layer 230′ is formed to entirely cover the top surface of the substrate 201 to overlap with the heating units 220.

Then, referring to FIG. 6B, a voltage is applied to the heating units 220 to form the organic material pattern 230, as will be described in detail below.

A suitable voltage is applied to the heating units 220 by using the power source 210 of FIG. 3. When the voltage is applied to the heating units 220, joule heat is generated by the heating unit 220 due to a preselected or predetermined resistance of the heating units 220. The generated joule heat is intensively delivered to regions of the organic material layer 230′ corresponding to the heating units 220, via the substrate 210. Thus, the regions of the organic material layer 230′ overlapping the heating units 220 are melted and removed by the joule heat.

Thus, the organic material pattern 230 is formed having apertures 230a corresponding to the heating units 220.

In the current embodiment, the organic material pattern 230 may be formed using joule heat generated by the heating units 220 without having to use a wet process, e.g., a photolithographic process, thereby protecting the organic material pattern 230 from moisture. Accordingly, it is possible to form the organic material pattern 230 having high durability in a precise pattern.

In FIGS. 6A and 6B, the heating units 220 and the organic material layer 230′ are disposed apart from one another to not contact one another. Thus, it is possible to prevent the organic material layer 230′ from being abnormally degraded, which is caused by the contact between the heating units 220 and the organic material layer 230′ when joule heat is generated by the heating units 220.

Furthermore, the heating units 220 may be prevented from being polluted, which can happen when the organic material layer 230′ is degraded and remains on the heating units 220.

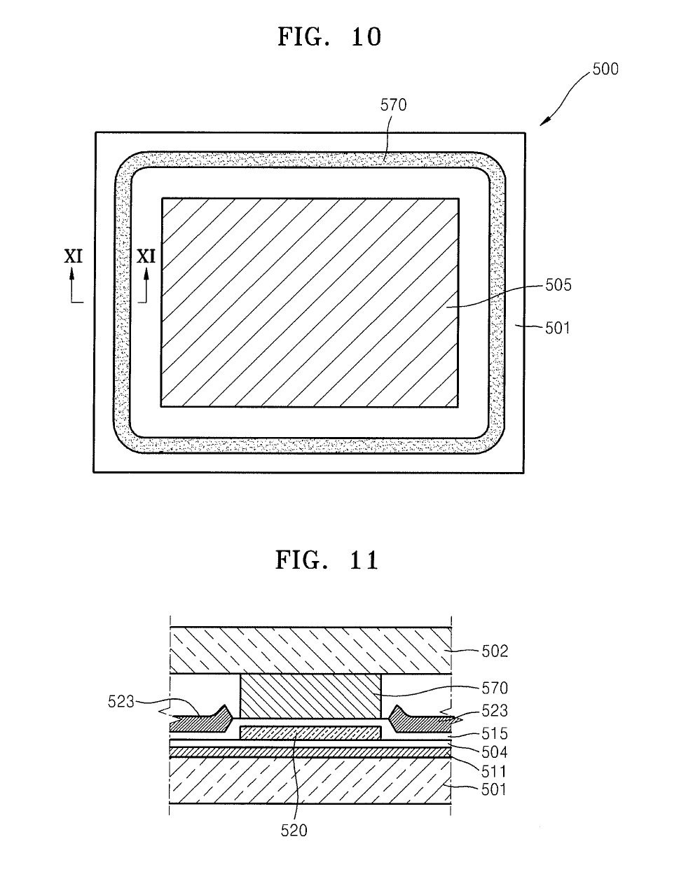

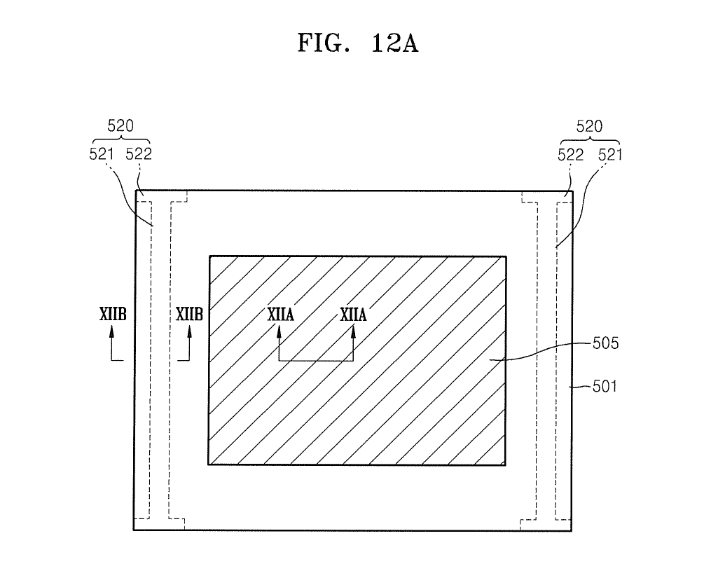

FIG. 7 is a schematic plan view of an apparatus 300 for forming an organic material pattern, according to another embodiment of the present invention. FIG. 8 is a cross-sectional view taken along the line VIII-VIII of FIG. 7.

Referring to FIGS. 7 and 8, the apparatus 300 is used to form a desired organic material pattern on a substrate (not shown).

To this end, heating units 320 are disposed on a base member 350. The heating units 320 are electrically connected to a power source 310 via a wiring unit 360.

The base member 350 may be formed of a SiO₂-based transparent glass material, but the present invention is not limited thereto and the base member 350 may be formed of a suitable heat-resistant material.

The heating units 320 are formed in a preselected or predetermined pattern on the base member 350. The heating units 320 may have any of various patterns. A pattern of the heating units 320 may be determined according to a desired shape of an organic material pattern to be formed on a substrate (not shown).

Each of the heating units 320 includes a body member 321 and connection members 322. The connection members 322 respectively form both ends of the heating unit 320. The body member 321 is located between the connection members 322. When a voltage is applied to the heating units 320 by the power source 310, the heating units 320 generate joule heat. To this end, the heating units 320 may be formed of metal having a preselected or predetermined resistance.

The wiring unit 360 is connected to the heating units 320. More specifically, the wiring unit 360 is connected to the connection members 322 of the heating units 320. The wiring unit 360 is formed of a conductive material (e.g., metal).

The power source 310 is electrically connected to the wiring unit 360. The type of the power source 310 is not limited. In other words, any of various types of devices capable of applying a suitable voltage to the heating units 320, and controlling a level of the voltage to be applied to the heating units 320 and a period of time for applying the voltage, may be employed as the power source 310.

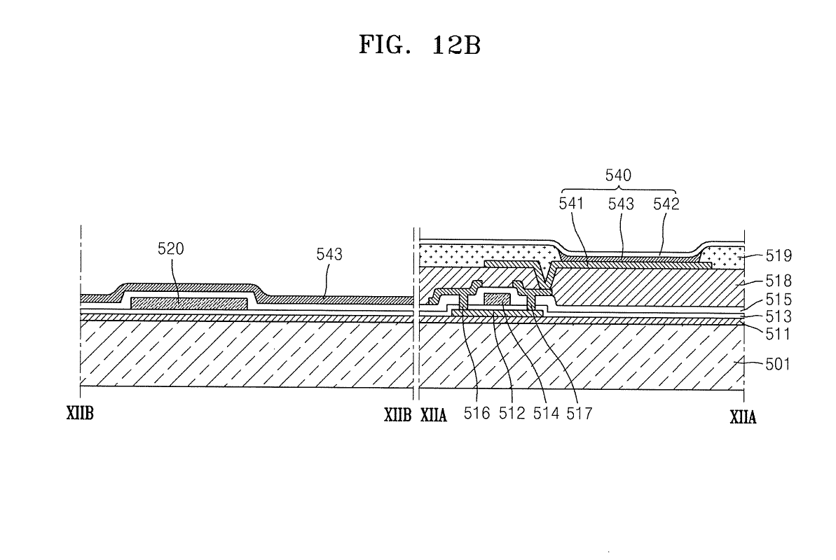

FIGS. 9A and 9B are cross-sectional views illustrating a method of forming an organic material pattern by using the apparatus 300 illustrated in FIGS. 7 and 8, according to another embodiment of the present invention.

First, referring to FIG. 9A, a substrate 301 is disposed to face the base member 350, and an organic material layer 330′ that is a material for forming an organic material pattern 330 is formed on the substrate 301.

More specifically, the substrate 301 is disposed to face the surface of the base member 350 on which the heating units 320 are disposed. Thus, the heating units 320 face the substrate 301, and the heating units 320 may contact the substrate 301.

The organic material layer 330′ is formed on a surface of the substrate 301 opposite to a surface of the substrate 301 that faces the heating units 320. In the example of FIG. 9A, the organic material layer 330′ is formed on a top surface of the substrate 301 to entirely cover the top surface of the substrate 301 and to overlap with the heating units 320.

Then, referring to FIG. 9B, a voltage is applied to the heating units 320 to form the organic material pattern 330, as will be described in detail below.

A suitable voltage is applied to the heating units 320 by using the power source 310 of FIG. 6. When the voltage is applied to the heating units 320, joule heat is generated by the heating unit 320 due to a preselected or predetermined resistance of the heating units 320. The generated joule heat is intensively delivered to regions of the organic material layer 330′ corresponding to the heating units 320, via the substrate 310. Thus, the regions of the organic material layer 330′ overlapping with the heating units 320 are melted and removed by the joule heat.

Thus, the organic material pattern 330 is formed having apertures 330a corresponding to the heating units 320.

In the current embodiment, the organic material pattern 330 may be formed using joule heat generated by the heating units 320 without having to use a wet process, e.g., a photolithographic process, thereby protecting the organic material pattern 330 from moisture. Accordingly, it is possible to form the organic material pattern 330 having a precise pattern and high durability.

In particular, the heating units 320 and the organic material layer 330′ are spaced apart and not in contact one another. Thus, it is possible to prevent the organic material layer 330′ from being abnormally degraded, which is caused by the contact between the heating units 320 and the organic material layer 330′ when joule heat is generated by the heating units 320.

Also, the heating units 320 may be prevented from being polluted, which can happen when the organic material layer 330′ is degraded and remains on the heating units 320.

Furthermore, since the heating units 320 are formed on the base member 350 other than the substrate 301, the heating units 320 are not present on the substrate 301 even after the organic material pattern 330 is formed on the substrate 301, thereby increasing utility of the substrate 301. Also, it is possible to repeatedly form the organic material pattern 330 on a plurality of substrates 301 by moving the base member 350, thereby increasing process efficiency.

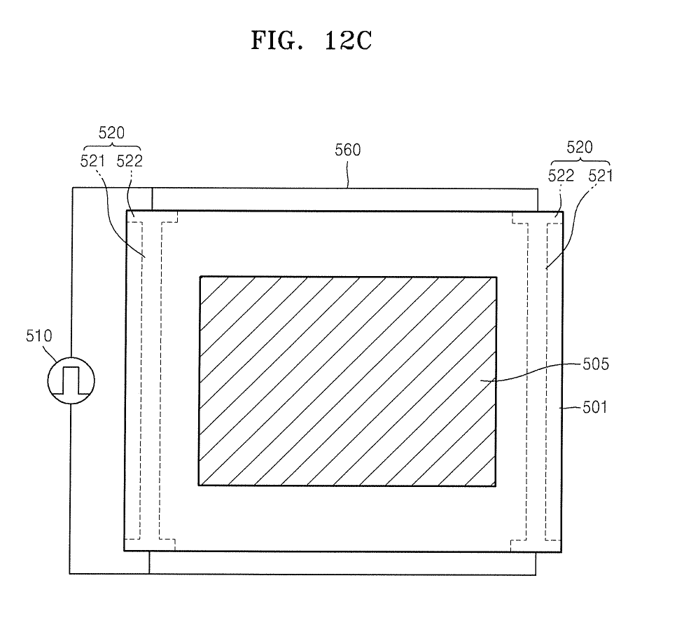

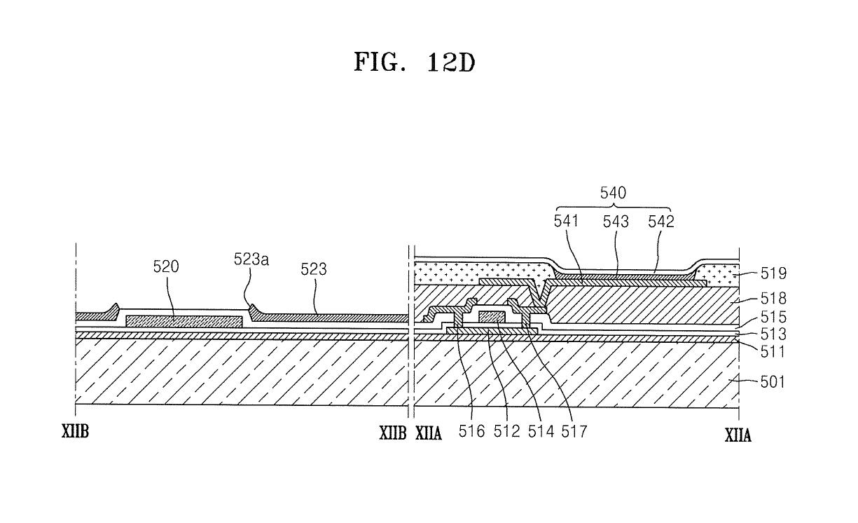

FIG. 10 is a schematic plan view of an organic light emitting display apparatus 500 according to an embodiment of the present invention. FIG. 11 is a cross-sectional view taken along the line XI-XI of FIG. 10.

The organic light emitting display apparatus 500 includes a substrate 501, a display unit 505, a heating unit 520, an organic material layer 523, a sealing member 570, and a sealing substrate 502.

Although not shown, the display unit 505 includes a plurality of organic light emitting devices. Each of the organic light emitting devices includes a first electrode, an intermediate layer, and a second electrode. The display unit 505 will be described in more detail when a method of manufacturing the organic light emitting display apparatus 500 according to an embodiment of the present invention is described below.

Referring to FIGS. 10 and 11, the heating unit 520 is formed in a region (e.g., a periphery region) of the substrate 501.

The organic material layer 523 is formed above the heating unit 520 not to overlap with the heating unit 520.

The sealing member 570 is disposed on the heating unit 520 to overlap with a preselected or predetermined region of the heating unit 520 and to be spaced apart from the organic material layer 523. The sealing member 570 is disposed between the substrate 501 and the sealing substrate 502 to wrap around the display unit 505.

However, the present invention is not limited thereto, and the organic light emitting display apparatus 500 may not include the sealing member 570 or the sealing substrate 502.

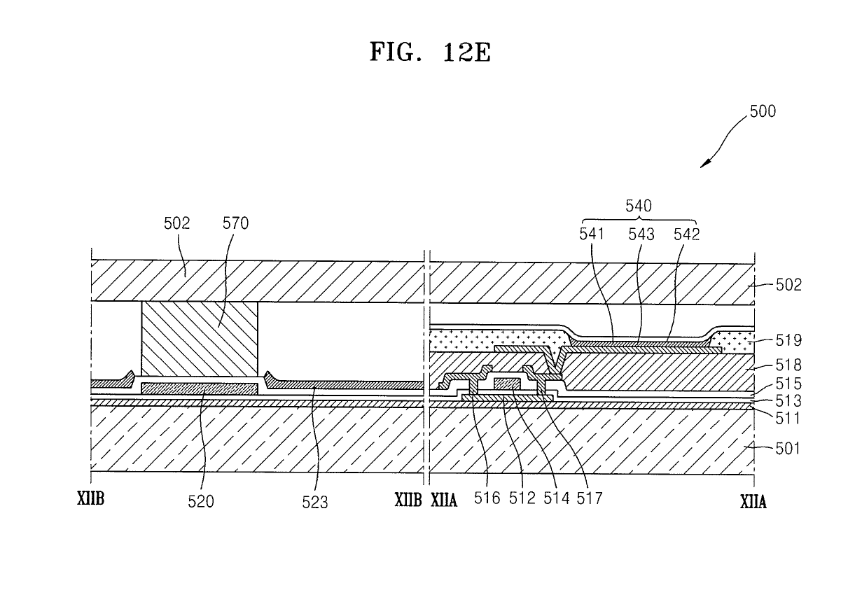

The structure of the organic light emitting display apparatus 500 according to the current embodiment will now be described in more detail with reference to FIGS. 12A to 12E.

FIG. 12A is a plan view, and FIGS. 12B through 12E are cross-sectional views sequentially illustrating a method of manufacturing the organic light emitting display apparatus 500 illustrated in FIGS. 10 and 11, according to an embodiment of the present invention.

First, the method will be described with reference to FIGS. 12A and 12B. FIG. 12B is a cross-sectional view taken along the lines XIIA-XIIA and XIIB-XIIB of FIG. 12A.

Referring to FIGS. 12A and 12B, a display unit 505 is formed on a substrate 501, and heating units 520 are disposed near the display unit 505. Specifically, the heating units 520 are disposed adjacent to respective edges of the substrate 501, e.g., left and right edges of the substrate 501. Each of the heating units 520 includes a body member 521 and connection members 522. The connection members 522 may correspond to side surfaces of the substrate 501, respectively. Thus, side surfaces of the connection members 522 may be exposed.

More specifically, a buffer layer 511 is formed on the substrate 501. The buffer layer 511 may be formed to entirely cover a top surface of the substrate 501, including the display unit 505 on the substrate 501 and surroundings of the display unit 505. The buffer layer 511 prevents or reduces impurity elements from penetrating via the substrate 501 and provides a substantially flat surface on the substrate 501. The buffer layer 511 may be formed of any suitable materials for enabling the above functions.

For example, the buffer layer 511 may contain an inorganic material, e.g., a silicon oxide, a silicon nitride, a silicon oxynitride, an aluminum oxide, an aluminum nitride, a titanium oxide, a titanium nitride, an organic material (e.g., polyimide, polyester, or acryl), or a stacked structure including a combination thereof. The buffer layer 511 is not an indispensable component and may thus be omitted if needed.

The display unit 505 may include a thin film transistor (TFT) disposed on the buffer layer 511. The TFT includes an active layer 512, a gate electrode 514, a source electrode 516, and a drain electrode 517.

First, the active layer 512 is formed in a preselected or predetermined pattern on the buffer layer 511. The active layer 512 may be formed of an inorganic semiconductor, e.g., amorphous silicon or poly silicon, an organic semiconductor, or an oxide semiconductor. The active layer 512 includes a source region, a drain region, and a channel region.

A gate insulating layer 513 is formed on the active layer 512. The gate insulating layer 513 may be formed to correspond to the entire substrate 501. In other words, the gate insulating layer 513 is formed on both the display unit 505 and the surrounding of the display unit 505. The gate insulating layer 513 insulates the active layer 512 from the gate electrode 514, and may be formed of an organic material or an inorganic material, e.g., SiNx or SiO₂.

The gate electrode 514 is formed on the gate insulating layer 513. The gate electrode 514 may contain gold (Au), silver (Ag), copper (Cu), nickel (Ni), platinum (Pt), palladium (Pd), aluminum (Al), molybdenum (Mo), an Al:Nd alloy, or an Mo:W alloy, but the present invention is not limited thereto, and any of other suitable materials may be used to form the gate electrode 514 according to design conditions.

The heating units 520 are formed near the display unit 505. The heating units 520 may be formed of the material used to form the gate electrode 514. The heating units 520 are formed near the edges of the substrate 501. In the current embodiment, the heating units 520 are formed on a layer on which the gate electrode 514 is formed by using the material of the gate electrode 514, but the present invention is not limited thereto. That is, the location and material of the heating units 520 on the substrate 501 are not limited. For example, the heating units 520 may be formed of a material used to form the source electrode 516 or the drain electrode 517, as will be described below.

An interlayer insulating layer 515 is formed on the gate electrode 514. The interlayer insulating layer 515 may be formed to correspond to all the surfaces of the substrate 501. In other words, the interlayer insulating layer 515 is formed on both the display unit 505 and the surroundings of the display unit 505 to cover the heating units 520.

The source electrode 516 and the drain electrode 517 are formed on the interlayer insulating layer 515. Specifically, the interlayer insulating layer 515 and the gate insulating layer 513 are formed to expose the source and drain regions of the active layer 512, and the source electrode 516 and the drain electrode 517 are formed to contact the exposed source and drain regions, respectively.

A passivation layer 518 is formed on the TFT. Specifically, the passivation layer 518 is formed on the source electrode 516 and the drain electrode 517.

An organic light emitting device 540 is formed on the passivation layer 518. The organic light emitting device 540 includes a first electrode 541, a second electrode 542, and an intermediate layer 543.

In more detail, the passivation layer 518 is formed to partially cover the drain electrode 517 so that a preselected or predetermined region of the drain electrode 517 may be exposed, and the first electrode 541 is formed to be connected to the exposed region of the drain electrode 517.

When the first electrode 541 functions as an anode, the first electrode 541 may include ITO, IZO, ZnO, or In₂O₃ having a high work function. According to various embodiments, the first electrode 541 may further include a reflective layer formed of silver (Ag), magnesium (Mg), aluminum (Al), platinum (Pt), palladium (Pd), gold (Au), nickel (Ni), neodymium (Nd), iridium (Ir), chromium (Cr), lithium (Li), ytterbium (Yb), or calcium (Ca).

A pixel defining layer 519 is formed on the first electrode 541 by using an insulating material. The pixel defining layer 519 is formed to expose a preselected or predetermined region of the first electrode 541.

The intermediate layer 543 is formed on the first electrode 541. In more detail, the intermediate layer 543 is formed to contact the exposed region of the first electrode 541.

The intermediate layer 543 includes an organic emission layer (not shown) to emit visible light. The intermediate layer 543, and particularly, the organic emission layer may be formed according to any of various methods known to those skilled in the art. For example, the organic emission layer may be formed according to a deposition process using a deposition mask. In this case, the intermediate layer 543 may remain on not only a preselected or predetermined region of the display unit 505, but also on outer walls of the display unit 505 to overlap with the heating units 520.

In particular, referring to FIG. 12A, if the deposition process is continuously performed on the substrate 501 in a direction from a left end of the substrate 501 to a right end of the substrate 501 so as to form the organic emission layer of the intermediate layer 543, then the intermediate layer 543 is also formed on regions adjacent to the left and right edges of the substrate 501. Thus, the intermediate layer 543 may overlap with the heating units 520.

In this case, certain regions of the intermediate layer 543, which surround the display unit 505, are not used for the function of the display unit 505, but may cause an error during a subsequent process, as will be described below.

The intermediate layer 543 may be formed of a low-molecular weight organic material or a high-molecular weight organic material. If the low-molecular weight organic material is used, then the intermediate layer 543 may include a hole injection layer (HIL), a hole transport layer (HTL), an emission layer (EML), an electron transport layer (ETL), and an electron injection layer (EIL).

The HIL may be formed of a phthalocyanine compound, e.g., copper phthalocyanine (CuPc), or starburst-type amines, e.g., TCTA, m-MTDATA, or m-MTDAPB.

The HTL may be formed of N,N′-bis(3-methylphenyl)-N,N′-diphenyl[1,1-biphenyl]-4,4′-diamine (TPD), or N,N′-di(naphthalene-1-yl)-N,N′-diphenyl benzidine (α-NPD).

The EIL may be formed of LiF, NaCl, CsF, Li2O, BaO, or Liq.

The ETL may be formed of tris-8-hydroxyquinoline aluminum (Alq3).

The organic emission layer may include a host material and a dopant material.

Examples of the host material of the organic emission layer may include tris(8-hydroxy-quinolinato)aluminum (Alq3), 9,10-di(naphth-2-yl)anthracene (AND), 3-tert-butyl-9,10-di(naphth-2-yl)anthracene (TBADN), 4,4′-bis(2,2-diphenyl-ethene-1-yl)-4,4′-dimethylphenyl (DPVBi), 4,4′-bis(2,2-diphenyl-ethene-1-yl)-4,4′-dimethylphenyl (p-DMDPVBi), tert(9,9-diarylfluorene)s (TDAF), 2-(9,9′-spirobifluorene-2-yl)-9,9′-spirobifluorene(BSDF), 2,7-bis(9,9′-spirobifluorene-2-yl)-9,9′-spirobifluorene (TSDF), bis(9,9-diarylfluorene)s (BDAF), 4,4′-bis(2,2-diphenyl-ethene-1-yl)-4,4′-di-(tert-butyl)phenyl (p-TDPVBi), 1,3-bis(carbazol-9-yl)benzene (mCP), 1,3,5-tris(carbazol-9-yl)benzene (tCP), 4,4′,4″-tris(carbazol-9-yl)triphenylamine (TcTa), 4,4′-bis(carbazol-9-yl)biphenyl (CBP), 4,4′-bis(9-carbazolyl)-2,2′-dimethyl-biphenyl (CBDP), 4,4′-bis(carbazol-9-yl)-9,9-dimethyl-fluorene (DMFL-CBP), 4,4′-bis(carbazol-9-yl)-9,9-bis(9-phenyl-9H-carbazol)fluorene (FL-4CBP), 4,4′-bis(carbazol-9-yl)-9,9-di-tolyl-fluorene (DPFL-CBP), 9,9-bis(9-phenyl-9H-carbazol)fluorene (FL-2CBP), and the like.

Examples of the dopant material of the organic emission layer may include 4,4′-bis[4-(di-p-tolylamino)styryl]biphenyl (DPAVBi), 9,10-di(naph-2-tyl)anthracene (ADN), 3-tert-butyl-9,10-di(naph-2-typanthracene (TBADN), and the like.

The second electrode 542 is formed on the intermediate layer 543. When the second electrode 542 functions as a cathode, the second electrode 542 may be formed of metal, e.g., silver (Ag), magnesium (Mg), aluminum (Al), platinum (Pt), palladium (Pd), gold (Au), nickel (Ni), neodymium (Nd), iridium (Ir), chromium (Cr), lithium (Li), or calcium (Ca). Also, the second electrode 542 may include ITO, IZO, ZnO, or In₂O₃ to pass light therethrough.

When a voltage is applied across the first electrode 541 and the second electrode 542, visible light is emitted from the organic emission layer of the intermediate layer 543 to form an image that a user can view.

Then, referring to FIGS. 12C and 12D, the organic material layer 523 is formed using the heating units 520.

More specifically, referring to FIG. 12C, a voltage is applied to the heating units 520 from a power source 510 via a wiring unit 560. In this case, the heating units 520 may be exposed so that the heating units 520 and the wiring unit 560 may be easily connected to one another. As described above, the connection members 522 of the heating units 520 are formed to correspond to edges of the substrate 501 so that side surfaces of the connection member 522 may be exposed and the exposed side surfaces may be connected to the wiring unit 560.

When voltage is applied to the heating units 520, joule heat is generated by the heating unit 520 due to a preselected or predetermined resistance of the heating units 520. The regions of the intermediate layer 543 that overlap with the heating units 520 are melted and removed due to the generated joule heat. Thus, as illustrated in FIG. 12D, the organic material pattern 523 is formed having apertures 523a corresponding to the heating units 520.

In this case, the shape of the organic material pattern 523 may vary according to the sizes and shapes of the heating unit 520, and the organic material pattern 523 may be connected to the intermediate layer 543.

Then, referring to FIG. 12E, a sealing member 570 and a sealing substrate 502 are disposed to complete the manufacturing of the organic light emitting display apparatus 500.

Specifically, the sealing member 570 overlaps with at least preselected or predetermined regions of the heating units 520. Also, a bottom surface of the sealing member 570 contacts the interlayer insulating layer 515, but is spaced apart from the organic material pattern 523. The sealing member 570 may be spaced apart from the organic material pattern 523. Thus, the sealing member 570 may be prevented from being physically or chemically degraded due to the contact with the organic material pattern 523.

The sealing member 570 is disposed near the display unit 505, and between the substrate 501 and the sealing substrate 502 to combine the substrate 501 with the sealing substrate 502. Thus, the organic light emitting device 540 may be protected from foreign substances, moisture, or external shocks.

In the current embodiment, the organic material pattern 523 may be formed using joule heat generated by the heating units 520 without having to use a wet process, e.g., a photolithographic process, thereby protecting the organic material pattern 523 from moisture.

Also, since the deposition process is performed on the substrate 501 toward a direction, the intermediate layer 543 remains even at the edges of the substrate 501 when the intermediate layer 543 is formed. The remnant intermediate layer 543 around the display unit 505 is not used for the function of the display unit 505, but may cause other elements from being polluted during manufacturing of the organic light emitting display apparatus 500. The remnant intermediate layer 543 may lower adhering strength between elements disposed at the edges of the substrate 501 and the substrate 502, thereby lowering the durability of the organic light emitting display apparatus 500.

In particular, the sealing substrate 502 may be disposed to face the substrate 501 to seal the display unit 505, and the sealing member 570 may be formed to combine the substrate 501 with the sealing substrate 502. In this case, when the sealing member 570 contacts the remnant intermediate layer 543 or is formed on the remnant intermediate layer 543, the characteristics of the sealing member 570 may be degraded or the adhering strength between the substrate 501 and the sealing substrate 502 may be reduced, thereby preventing the display unit 505 from being precisely sealed. However, according to the current embodiment, the organic material pattern 523 may be formed by easily removing a preselected region of the remnant intermediate layer 543 by using the heating units 520, and the sealing member 570 is formed to be disposed apart from the organic material pattern 523. Thus, it is possible to increase the adhering strength between the substrate 501 and the sealing substrate 502, thereby improving the durability of the organic light emitting display apparatus 500. Also, it is possible to prevent image quality characteristics of the display unit 505 from being degraded by effectively sealing the display unit 505.

Furthermore, the heating units 520 are formed in a layer of the TFT of the display unit 505, i.e., on the layer on which the gate electrode 514 is formed, by using the material used to form the gate electrode 514, thereby increasing process convenience.

In the current embodiment, the organic light emitting display apparatus 500 includes the sealing member 570 and the sealing substrate 502, but the present invention is not limited thereto. In other words, the organic light emitting display apparatus 500 may not include the sealing member 570 and the sealing substrate 502, and in this case, the organic material pattern 523 may also be easily formed by using the heating units 520. Also, the organic material pattern 523 may be formed in a desired pattern by forming the heating units 520 in any of various shapes.

Also, in the current embodiment, the heating units 520 are disposed in regions adjacent to the left and right edges of the substrate 501, but the present invention is not limited thereto, and the heating units 520 may be disposed in regions adjacent to upper and lower edges of the substrate 501.

Furthermore, when the organic light emitting display apparatus 500 is formed, the heating units 520 may be formed on a bottom surface of the substrate 501 as illustrated in FIG. 4 or may be formed on an additional base member (not shown) as illustrated in FIG. 7.

Accordingly, with a method and apparatus for forming an organic material pattern, an organic light emitting display apparatus, and a method of manufacturing an organic light emitting display apparatus according to various embodiments of the present invention, it is possible to easily improve durability and image quality characteristics of an organic light emitting display apparatus.

While the present invention has been particularly shown and described with reference to exemplary embodiments thereof, it will be understood by those of ordinary skill in the art that various changes in form and details may be made therein without departing from the spirit and scope of the present invention as defined by the following claims, and their equivalents.

What is claimed is:

1. An apparatus for forming an organic material pattern on a substrate, the apparatus comprising:
a heater overlapping with a region of the substrate different from another region of the substrate in which the organic material pattern is to be formed;
a power source for applying a voltage to the heater; and
wiring for electrically connecting the power source with the heater.

2. The apparatus of claim 1,
wherein the heater comprises connection members and a body member,
wherein the connection members respectively form both ends of the heater to be connected to the wiring, and
wherein the body member is located between the connection members.

3. The apparatus of claim 1, wherein the heater is on a surface of the substrate on which the organic material pattern is to be formed.

4. The apparatus of claim 1, wherein the heater is on a surface of the substrate opposite to another surface of the substrate on which the organic material pattern is to be formed.

5. The apparatus of claim 1, further comprising a base member facing a surface of the substrate opposite to another surface of the substrate on which the organic material pattern is to be formed, and
wherein the heater is formed on a surface of the base member facing the substrate.

6. The apparatus of claim 5, wherein the heater is in contact with the substrate.

7. A method of forming an organic material pattern on a substrate, the method comprising:
preparing a heater to overlap with a region of the substrate different from another region of the substrate in which the organic material pattern is to be formed, a power source to apply a voltage to the heater, and wiring to electrically connect the power source with the heater;
forming an organic material layer on the substrate, the organic material layer being a material for forming the organic material pattern; and
applying a voltage to the heater from the power source to remove at least a region of the organic material layer corresponding in position to the heater by using joule heat generated by the heater.

8. The method of claim 7, wherein the heater comprises connection members and a body member,
wherein the connection members respectively form both ends of the heater to be connected to the wiring, and
the body member is located between the connection members.

9. The method of claim 7, wherein the heater is formed on a surface of the substrate, and
the organic material layer is formed on the surface of the substrate and covers the heater.

10. The method of claim 7, wherein the heater is formed on a surface of the substrate opposite to another surface of the substrate on which the organic material pattern is to be formed.

11. The method of claim 7, further comprising preparing a base member to face a surface of the substrate opposite to another surface of the substrate on which the organic material pattern is to be formed on the substrate,
wherein the heater is formed on a surface of the base member facing the surface of the substrate, and
wherein the organic material layer is formed on the another surface of the substrate opposite to the surface of the substrate facing the heater.

12. The method of claim 7, wherein the heater is in contact with the substrate.

13. The method of claim 7, wherein the organic material pattern comprises an aperture corresponding in position to the heater.

14. An organic light emitting display apparatus, the apparatus comprising:
a substrate;
a display unit on the substrate and comprising an organic light emitting device, the organic light emitting device comprising a first electrode, a second electrode, and an intermediate layer, the intermediate layer being disposed between the first electrode and the second electrode and comprising an organic emission layer;
a heater adjacent the display unit; and
an organic material pattern, the organic material pattern and the heater overlapping different regions of the substrate, respectively.

15. The apparatus of claim 14, further comprising:
a sealing substrate facing the substrate; and
a sealing member between the substrate and the sealing substrate and adjacent to the display unit,
wherein a region of the heater overlaps with the sealing member.

16. The apparatus of claim 15, wherein a bottom surface of the sealing member is spaced apart from at least the organic material pattern.

17. The apparatus of claim 15, wherein the sealing member is spaced apart from the organic material pattern.

18. The apparatus of claim 15, further comprising at least one insulating layer between the heater and the sealing member.

19. The apparatus of claim 14, further comprising a thin film transistor (TFT) being electrically connected to the organic light emitting device, the TFT comprising an active layer, a gate electrode, a source electrode, and a drain electrode,
wherein the heater comprises a material used to form at least one from among the gate electrode, the source electrode, and drain electrode.

20. The apparatus of claim 19, further comprising an interlayer insulating layer between the gate electrode and the source electrode, and between the gate electrode and the drain electrode,
wherein the heater comprises a material used to form the gate electrode, and
wherein the interlayer insulating layer is on the heater.

21. The apparatus of claim 14, wherein the organic material pattern comprises a material used to form the intermediate layer.

22. The apparatus of claim 14, wherein the organic material pattern is connected to a region of the intermediate layer.

23. The apparatus of claim 14, wherein ends of the heater correspond to end portions of the substrate, respectively.

24. The apparatus of claim 14, wherein the heater comprises connection members and a body member,
wherein the connection members respectively form both ends of the heater,
the body member is located between the connection members, and
the connection members are formed to respectively correspond to end portions of the substrate in such a manner that side surfaces of the connection members are exposed.

25. A method of manufacturing an organic light emitting display apparatus, the method comprising:
forming a display unit on a substrate, the display unit comprising an organic light emitting device, the organic light emitting device comprising a first electrode, a second electrode, and an intermediate layer, the intermediate layer being between the first electrode and the second electrode and comprising an organic emission layer;
forming a heater adjacent to the display unit;
forming an organic material layer on the substrate; and
applying a voltage to the heater from a power source to remove at least a region of the organic material layer corresponding in position to the heater by using joule heat generated by the heater.

26. The method of claim 25, wherein, if the voltage is applied to the heater from the power source to remove at least the region of the organic material layer corresponding in position to the heater by using the joule heat generated by the heater, then an organic material pattern having an aperture corresponding in position to the heater is formed.

27. The method of claim 25, wherein the power source and the heater are electrically connected via wiring.

28. The method of claim 25, wherein the organic material layer comprises a material used to form the intermediate layer during the formation of the intermediate layer.

29. The method of claim 25, further comprising:
preparing a sealing substrate to face the substrate; and
forming a sealing member between the substrate and the sealing substrate, and adjacent the display unit,
wherein the sealing member overlaps with at least a region of the heater.

30. The method of claim 29, wherein the forming of the sealing member is performed after the heater is formed and the region of the organic material layer corresponding in position to the heater has been removed.

31. The method of claim 29, wherein the sealing member is formed to be spaced apart from the organic material layer.

32. The method of claim 29, further comprising forming at least one insulating layer between the heater and the sealing member.

33. The method of claim 25, further comprising forming a thin film transistor (TFT) to be electrically connected to the organic light emitting device, the TFT comprising an active layer, a gate electrode, a source electrode, and a drain electrode,
wherein the heater comprises a material used to form at least one from among the gate electrode, the source electrode, and the drain electrode.
